(19) United States
(12) Patent Application Publication
(10) Pub. No.: US 2025/0368566 A1
(43) Pub. Date: Dec. 4, 2025

(54) METHOD FOR MANUFACTURING WINDOW AND ELECTRONIC DEVICE INCLUDING THE SAME WINDOW

(71) Applicant: Samsung Display Co., LTD., Yongin-si (KR)

(72) Inventors: BYOUNGYUL SHIM, Yongin-si (KR); DONGHO KIM, Yongin-si (KR); HYUNCHUL KIM, Yongin-si (KR); JUSUK OH, Yongin-si (KR); KANG DUK CHOI, Yongin-si (KR); SEUNGPYO HONG, Yongin-si (KR)

(21) Appl. No.: 19/221,875

(22) Filed: May 29, 2025

(30) Foreign Application Priority Data
May 31, 2024 (KR) 10-2024-0071456

(51) Int. Cl. C03C 15/02; H10K 59/12; H10K 59/80; H10K 71/00

(52) U.S. Cl. CPC C03C 15/02; H10K 59/1201; H10K 59/873; H10K 71/821

(57) ABSTRACT

A method for manufacturing a window includes providing a glass substrate including a first non-folding region, a second non-folding region, and a folding region interposed between the first non-folding region and the second non-folding region, forming a photoresist layer on the glass substrate, forming an opening pattern in the photoresist layer, wherein the opening pattern overlaps with the folding region and exposes the glass substrate, etching the glass substrate by supplying a first etchant to the glass substrate exposed through the opening pattern, removing the photoresist layer having the opening pattern, and polishing at least a portion of the glass substrate by supplying a second etchant to a top surface of the glass substrate.

This application claims priority to Korean Patent Application No. 10-2024-0071456, filed on May 31, 2024, and all the benefits accruing therefrom under 35 U.S.C. § 119, the content of which in its entirety is herein incorporated by reference.

### BACKGROUND

Embodiments of the present disclosure described herein relate to a method for manufacturing a window and electronic device including the same window, and more particularly, relate to a method for manufacturing a window of a foldable electronic device.

A display device includes a display region activated in response to an electrical signal. The display device may sense an input applied from the outside through a display region while displaying various images to be provided for a user. Recently, as display devices in various shapes are developed, the studies and researches have been actively performed on, especially, a foldable display device. Techniques for etching and polishing ultra-thin glass (UTG) which support realizing the characteristics of the foldable electronic device are desired.

### SUMMARY

Embodiments of the present disclosure provide a window improved in the strength of impact resistance and the defective outer appearance.

According to the present disclosure, a method for manufacturing a window may include providing a glass substrate including a first non-folding region, a second non-folding region, and a folding region interposed between the first non-folding region and the second non-folding region, forming a photoresist layer on the glass substrate, forming an opening pattern in the photoresist layer, wherein the opening pattern overlaps with the folding region and exposes the glass substrate, etching the glass substrate by supplying first etchant to the glass substrate exposed through the opening pattern, removing the photoresist layer having the opening pattern, and polishing at least a portion of the glass substrate by supplying second etchant to a top surface of the glass substrate.

The first etchant may be the same as the second etchant.

The second etchant may be supplied to an entirety of the top surface of the glass substrate in the polishing of the at least a portion of the glass substrate.

A recess may be formed in at least a portion of the folding region, in the etching of the glass substrate.

A first flat part, a second flat part, and an initial recess part interposed between the first flat part and the second flat part may be formed on the glass substrate in the etching of the glass substrate.

The initial recess part may include a first step part adjacent to the first non-folding region, a second step part adjacent to the second non-folding region, and a third flat part interposed between the first step part and the second step part, in the etching of the glass substrate.

A recess part may be formed from the initial recess part, in the polishing of the at least the portion of the glass substrate, a portion, of the first step part may be polished and the polishing of the portion of the first step part forms a first sloped part curved in the portion, of the first step part, wherein the portion of the first step part which is polished and in which the first sloped part is formed is adjacent to a boundary between the first non-folding region and the folding region, and a portion, of the second step part may be polished, and the polishing of the portion of the second step part forms a second sloped part curved in the portion, which is adjacent to the boundary between the second non-folding region and the folding region, of the second step part, wherein the portion of the second step part which is polished and in which the second sloped part is formed is adjacent to a boundary between the second non-folding region and the folding region and the recess part comprises the first sloped part, the second sloped part, and the third flat part.

The second etchant may be supplied to the portion, which is adjacent to the boundary between the first non-folding region and the folding region, of the first step part, and the portion, which is adjacent to the boundary between the second non-folding region and the folding region, of the second step part, in the polishing of the at least the portion of the glass substrate.

The polishing of the at least the portion of the glass substrate may be performed using a polishing tool.

The polishing tool may be provided such that the polishing tool overlaps with an entirety of the top surface of the glass substrate.

The polishing tool may include a porous material.

The polishing tool may include a first polishing tool and a second polishing tool, the first polishing tool may be provided such that the first polishing tool overlaps with a portion, which is adjacent to the boundary between the first non-folding region and the folding region, of the first step part, and the second polishing tool may be provided such that the second polishing tool overlaps with the portion, which is adjacent to the boundary between the second non-folding region and the folding region, of the second step part.

The first polishing tool may be provided to have a portion overlapped with a portion, which is adjacent to the first non-folding region, of the first step part and is flat, and to make contact with a top surface in the flat part, and the second polishing tool may be provided to have a portion overlapped with a portion, which is adjacent to the second non-folding region, of the second step part and is flat, and to make contact with a top surface in the flat part, and

The polishing tool includes a first polishing tool and a second polishing tool each provided in a cylinder shape or a polygonal prism shape.

The polishing tool includes a first polishing tool and a second polishing tool respectively provided as the same prism shape.

The polishing tool includes a first polishing tool and a second polishing tool respectively provided as different prism shapes.

According to the present disclosure, the method for manufacturing the window may further include forming a masking pattern configured to cover a portion of the top surface of the glass substrate, after removing the photoresist layer having the opening pattern and before polishing the at least a portion of the glass substrate.

According to the present disclosure, a method for manufacturing a window may include providing a glass substrate including a first non-folding region, a second non-folding region, and a folding region interposed between the first non-folding region and the second non-folding region, forming a photoresist layer on the glass substrate, forming an opening pattern in the photoresist layer, wherein the opening pattern overlaps with the folding region and exposes the glass substrate, etching the glass substrate by supplying first etchant to the glass substrate exposed through the opening pattern, removing the photoresist layer having the opening pattern, forming a masking pattern configured to cover a portion of a top surface of the glass substrate, and polishing at least a portion of the glass substrate, in which a first flat part, a second flat part, and an initial recess part interposed between the first flat part and the second flat part may be formed on the glass substrate in the etching of the glass substrate.

The masking pattern may be absent on a portion, which is to be polished, of the top surface of the glass substrate.

In the polishing of the at least a portion of the glass substrate, second etchant may be supplied to the top surface of the glass substrate, and the first etchant may be the same as the second etchant.

The initial recess part may include a first step part adjacent to the first non-folding region, a second step part adjacent to the second non-folding region, and a third flat part interposed between the first step part and the second step part.

The masking pattern may include a first masking pattern, a second masking pattern, and a third masking pattern, and the first masking pattern may be disposed on the first flat part, the second masking pattern is disposed on the second flat part, and the third masking pattern is disposed on the third flat part.

The first step part may include a part adjacent to the first non-folding region and flat, and a part adjacent to the third flat part and sloped, and the second step part may include a part adjacent to the second non-folding region and flat, and a part adjacent to the third flat part and inclined.

A recess part may be formed from the initial recess part, in the polishing of the at least a portion of the glass substrate, a portion, of the first step part is polished, and the polishing of the portion of the first step part forms a first sloped part curved in the portion of the first step part, wherein the portion of the first step part which is polished and in which the first sloped part is formed is adjacent to a boundary between the first non-folding region and the folding region, and a portion, of the second step part is polished, and the polishing of the portion of the second step part forms a second sloped part curved in the portion of the second step part, wherein the portion of the second step part which is polished and in which the second sloped part is formed is adjacent to a boundary between the second non-folding region and the folding region, and the recess part may comprise the first sloped part, the second sloped part, and the third flat part.

According to the present disclosure, in the method for manufacturing the window, the polishing of the at least the portion of the glass substrate may be performed using a polishing tool.

The polishing tool may be provided such that a portion of the polishing tool overlaps with the masking pattern.

The polishing tool may include a first polishing tool and a second polishing tool, the first polishing tool may be provided between the first masking pattern and the second masking pattern, and the second polishing tool may be provided between the second masking pattern and a third masking pattern.

According to the present disclosure, an electronic device may include a window manufactured by a method comprising providing a glass substrate including a first non-folding region, a second non-folding region, and a folding region interposed between the first non-folding region and the second non-folding region, forming a photoresist layer on the glass substrate, forming an opening pattern in the photoresist layer, wherein the opening pattern overlaps with the folding region and exposes the glass substrate, etching the glass substrate by supplying a first etchant to the glass substrate exposed through the opening pattern, removing the photoresist layer having the opening pattern and polishing at least a portion of the glass substrate by supplying a second etchant to a top surface of the glass substrate.

### BRIEF DESCRIPTION OF THE FIGURES

The above and other objects and features of the present disclosure will become apparent by describing in detail embodiments thereof with reference to the accompanying drawings.

FIG. 1A is a assembling perspective view illustrating a display device in an unfolding status according to an embodiment of the present disclosure;

FIG. 1B is a assembling perspective view illustrating a display device in an inner-folding status according to an embodiment of the present disclosure;

FIG. 2 is an exploded perspective view of a display device according to an embodiment of the present disclosure.

FIG. 3 is a cross-sectional view of a window according to an embodiment of the present disclosure.

FIGS. 4A to 4F cross-sectional views schematically illustrating steps in a method for manufacturing a window according to an embodiment of the present disclosure.

FIG. 5A is a perspective view schematically illustrating a polishing step in a method for manufacturing a window according to an embodiment of the present disclosure.

FIG. 5B is a cross-sectional view schematically illustrating a polishing step in a method for manufacturing a window according to an embodiment of the present disclosure.

FIG. 6 is a cross-sectional view schematically illustrating a polishing step in a method for manufacturing a window according to an embodiment of the present disclosure.

FIGS. 7A and 7B are cross-sectional views schematically illustrating a polishing step in a method for manufacturing a window according to an embodiment of the present disclosure.

FIGS. 8A and 8B are cross-sectional views schematically illustrating a polishing step in a method for manufacturing a window according to an embodiment of the present disclosure.

### DETAILED DESCRIPTION

In the specification, the expression that a first component (or region, layer, part, portion, or the like) is “on”, “connected to”, or “coupled to” a second component means that the first component is directly on, connected to, or coupled to the second component or means that a third component is interposed therebetween.

The same reference numeral will be assigned to the same component. In some aspects, in drawings, thicknesses, proportions, and dimensions of components may be exaggerated to describe the technical features effectively. The term “and/or” includes any and all combinations of one or more of associated components.

Although the terms “first”, or “second”, may be used to describe various components, the components should not be construed as being limited by the terms. The terms are used to distinguish one component from another component. For example, without departing from the scope and spirit of the present disclosure, a first component may be referred to as a second component, and similarly, the second component may be referred to as the first component. The singular forms are intended to include the plural forms unless the context clearly indicates otherwise.

In some aspects, the terms “under”, “at a lower portion”, “above”, and “an upper portion” are used to describe the relationship between components illustrated in drawings. The terms are relative and are described with reference to a direction indicated in the drawing.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

It will be further understood that the terms “comprises”, “comprising”, “includes”, or “including”, or “having” specify the presence of stated features, numbers, steps, operations, components, parts, or the combination thereof, but do not preclude the presence or addition of one or more other features, numbers, steps, operations, components, components, and/or the combination thereof.

Unless defined otherwise, all terms (including technical terms and scientific terms) used in the specification have the same meaning as commonly understood by one skilled in the art to which the present disclosure pertains. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments according to the present disclosure will be described.

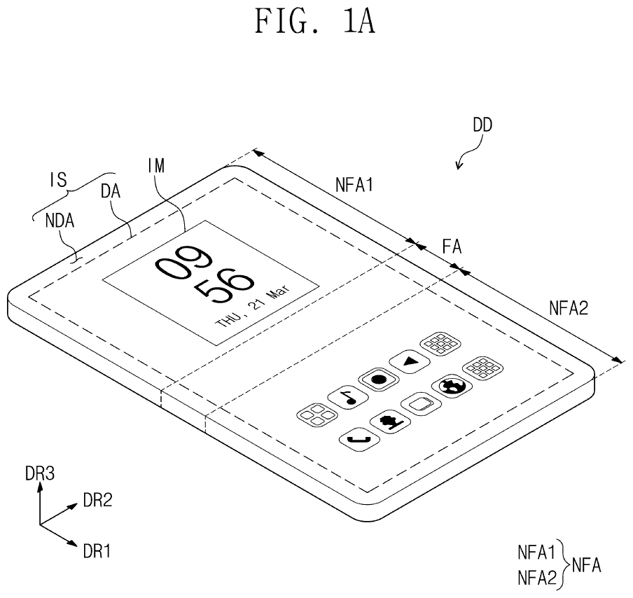

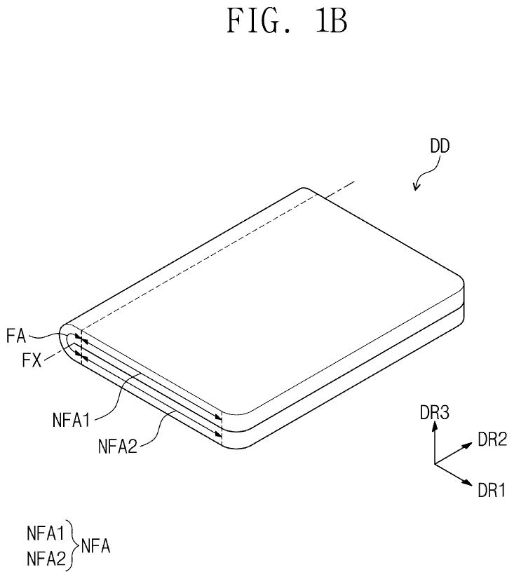

FIGS. 1A and 1B are perspective views illustrating a display device DD according to an embodiment of the present disclosure. FIG. 1A illustrates an unfolding state, and FIG. 1B illustrates a folding state.

Referring to FIGS. 1A and 1B, a display device DD (or a flexible display device DD) according to an embodiment of the present disclosure may include a display surface IS defined by a first direction DR1 and a second direction DR2 crossing the first direction DR1. The display device DD may provide an image IM to a user through the display surface IS.

Hereinafter, a direction substantially perpendicular to a plane defined by the first direction DR1 and the second direction DR2 is defined as a third direction DR3. The third direction DR3 may serve as a basis for distinguishing between a front surface and a rear surface of members. In the present disclosure, the wording “in a plan view” may refer to the state when viewed in the third direction DR3. Hereinafter, the first to third directions DR1, DR2, and DR3 are directions indicated by first to third direction axes, respectively, and the directions indicated by the first to third direction axes may be assigned with the same reference numerals.

FIGS. 1A and 1B illustrate a foldable display device as an example of the flexible display device DD. However, the flexible display device according to the present disclosure may be a rollable display device or a bendable display device, which is curled, and embodiments of the present disclosure are not limited thereto. According to the present disclosure, the flexible display device DD may include a large-size electronic device, such as, for example, a television or a monitor, or a small or medium-size electronic device, such as, for example, a cellular phone, a tablet, a vehicle navigation, a game machine, or a smartwatch. Hereinafter, the display device DD will be described as the foldable display device.

As illustrated in FIG. 1A, the display surface IS of the display device DD may include a plurality of regions. The display device DD includes a display region DA for displaying the image IM and a non-display region NDA adjacent to the display region DA. The non-display region NDA is a region in which the image is not displayed. FIG. 1A illustrates a watch widget as one example of the image IM. For example, the display region DA may be in a rectangular shape. The non-display region NDA may surround the display region DA. However, embodiments of the present disclosure are not limited thereto. For example, the shape of the display region DA and the shape of the non-display region NDA may be relatively designed. According to an embodiment, the non-display region NDA may be omitted.

The display device DD may include a folding region FA and a plurality of non-folding regions NFA. The non-folding regions NFA may include a first non-folding region NFA1 and a second non-folding region NFA2. The folding region FA may be interposed between the first non-folding region NFA1 and the second non-folding region NFA2 in the first direction DR1.

As illustrated in FIG. 1B, the folding region FA may be folded about a folding axis FX parallel to the second direction DR2. The first non-folding region NFA1 and the second non-folding region NFA2 may face each other, and the display device DD may be in an inner-folding status in which the display surface IS is prevented from being exposed to the outside.

When the display device DD includes two non-folding regions NFA, the non-folding regions NFA may have equal areas, but an embodiment is not limited thereto. The area of the non-folding region NFA may be larger than the folding region FA. According to an embodiment, the area of the folding region FA is not constant, and varied depending on the radius of curvature.

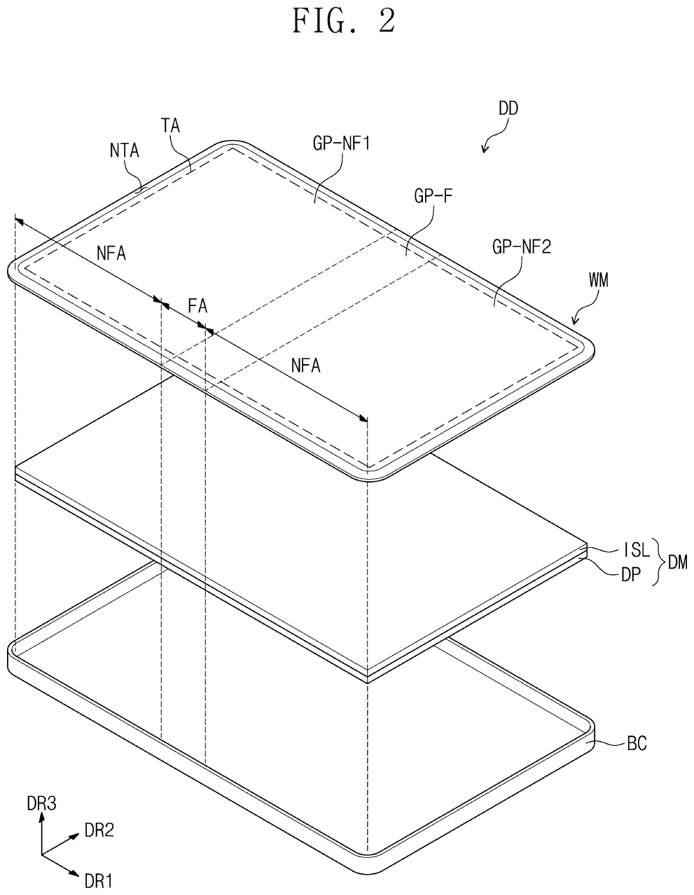

FIG. 2 is an exploded perspective view of the display device DD according to an embodiment of the present disclosure.

Referring to FIG. 2, the display device DD may include a window WM, a display module DM, and a receiving member BC.

The window WM may be disposed on the display module DM, and may transmit an image, which is provided from the display module DM, to the outside. The window WM includes a transmission region TA and a non-transmission region NTA. The transmission region TA may overlap with the display region DA, and may have the shape corresponding to the shape of the display region DA. The image IM displayed on the display region DA of the display device DD may be viewed from the outside through the transmission region TA of the window WM.

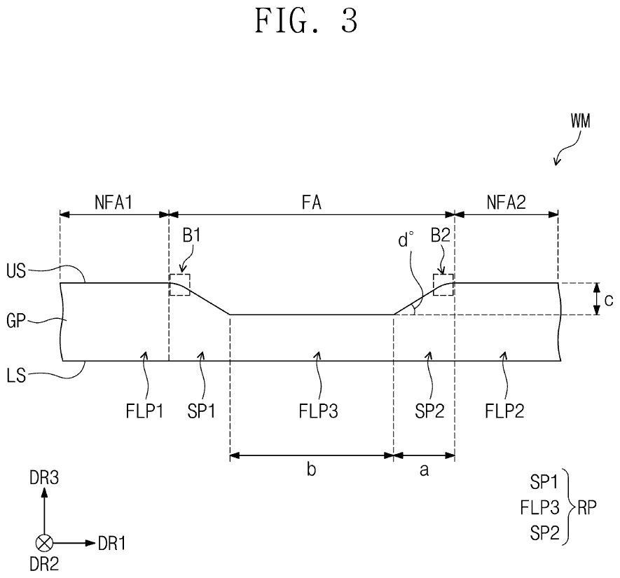

The window WM may include a glass substrate GP (see FIG. 3). The glass substrate GP (see FIG. 2) constituting the window WM may be an ultra-thin glass substrate having the thickness ranging from 20 μm to 100 μm. The glass substrate GP may have an ultra-thin thickness for the flexible display device DD which is foldable or bendable. For example, the thickness of the glass substrate GP (see FIG. 3) may be 30 μm.

The non-transmission region NTA may overlap with the non-display region NDA and may have the shape corresponding to the shape of the non-display region NDA. The non-transmission region NTA may be a region having light transmittance lower than light transmittance of the transmission region TA. However, the technical spirit of the present disclosure is not limited thereto. For example, the non-transmission region NTA may be omitted.

The window WM may include a folding part GP-F, and non-folding parts GP-NF1 and GP-NF2. The folding part GP-F of the window WM may correspond to the folding region FA of the display device DD. The non-folding parts GP-NF1 and GP-NF2 of the window WM may correspond to the non-folding regions NFA1 and NFA2 of the display device DD. Referring to FIG. 2, although the non-folding parts GP-NF1 and GP-NF2 include the first non-folding part GP-NF1 and the second non-folding part GP-NF2 spaced apart from each other while interposing the folding part GP-F between the first non-folding part GP-NF1 and the second non-folding part GP-NF2. The shape and the number of the folding part GP-F and the non-folding parts GP-NF1 and GP-NF2 may be variously changed to correspond to the shape and the number of the folding region FA and the non-folding regions NFA.

The display module DM is interposed between the window WM and the receiving member BC. The display module DM may include the display panel DP and an input sensing layer ISL disposed on the display panel DP. The display panel DP may generate an image and may transmit the generated image to the window WM. According to an embodiment of the present disclosure, the display panel DP may be a light emissive-type display panel, but embodiments of the present disclosure are not limited thereto. For example, the display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot and a quantum rod. Hereinafter, the display panel DP according to an embodiment will be described as an organic light emitting display panel.

The input sensing layer ISL may be interposed between the window WM and the display panel DP. As illustrated in FIG. 2, the input sensing layer ISL may be fully overlapped with the transmission region TA. However, according to an embodiment of the present disclosure, the input sensing layer ISL may overlap with only a portion of the transmission region TA or may overlap with only the non-transmission region NTA. The input sensing layer ISL senses an input applied from the outside. The input applied from the outside may be provided in various forms. For example, the external input may include any one of various external inputs, such as, for example, a part of a physical body of the user, a stylus pen, light, heat, or pressure. In some aspects, the external input may be not only a touch input by a part, such as, for example, a hand, of the physical body of the user, but also a space touch (e.g., hovering) made as the user approaches the display device DD or is close to the display device DD.

The input sensing layer ISL may sense the external input to obtain coordinate information for the external input. The input sensing layer ISL according to an embodiment of the present disclosure may sense the external input by sensing the change in capacitance due to an external object. In other words, the input sensing layer ISL according to an embodiment may be a capacitive input sensor.

The receiving member BC may receive the display module DM. Although not illustrated, the receiving member BC may include a hinge. The hinge may be provided in a portion, which is overlapped with the folding region FA, of the receiving member BC. According to an embodiment, the receiving member BC may be omitted.

FIG. 3 is a cross-sectional view of the window WM according to an embodiment of the present disclosure.

Referring to FIG. 3, the window WM may include the glass substrate GP. The glass substrate GP may include the first non-folding region NFA1, the second non-folding region NFA2, and the folding region FA between the first and second non-folding regions NFA1 and NFA2. The first non-folding region NFA1, the second non-folding region NFA2, and the folding region FA defined in the glass substrate GP may correspond to the first non-folding region NFA1 (see FIG. 1A), the second non-folding region NFA2 (see FIG. 1A), and the folding region FA defined in the display device DD (see FIG. 1A).

The glass substrate GP may include a first flat part FLP1, a second flat part FLP2, and a recess part RP between the first flat part FLP1 and the second flat part FLP2. The first flat part FLP1 may correspond to the first non-folding region NFA1, the second flat part FLP2 may correspond to the second non-folding region NFA2, and the recess part RP may correspond to the folding region FA. The recess part RP may be recessed from the first and second flat parts FLP1 and FLP2 in a thickness direction of the glass substrate GP. In other words, the thickness of the glass substrate GP may be smaller than the thickness of the glass substrate GP in the first and second flat parts FLP1 and FLP2. The recess part RP may be formed by supplying second etchant ES2 to be described herein and polishing at least a portion of the glass substrate GP.

The recess part RP may include a first sloped part SP1 adjacent to the first non-folding region NFA1, a second sloped part SP2 adjacent to the second non-folding region NFA2, and a third flat part FLP3 interposed between the first and second sloped parts SP1 and SP2.

The first sloped part SP1 may be defined from a point, at which the glass substrate GP is started being recessed from the first flat part FLP1 in the thickness direction of the glass substrate GP, to a point at which the glass substrate GP is started being parallel to a bottom surface LS of the glass substrate GP. The second sloped part SP2 may be defined from a point, at which the glass substrate GP is started being recessed from the second flat part FLP2 in the thickness direction of the glass substrate GP, to a point at which the glass substrate GP is started being parallel to the bottom surface LS of the glass substrate GP. The third flat part FLP3 may be defined as a part parallel to the bottom surface LS of the glass substrate GP.

A portion, which is adjacent to the boundary between the first non-folding region NFA1 and the folding region FA, of the first sloped part SP1 may have the shape curved in the thickness direction of the glass substrate GP, and a top surface US of the glass substrate GP in the portion may be formed as a curved surface. In other words, the top surface US of the glass substrate GP may include a curved part (hereinafter, referred as a “first curved part B1”) in the portion adjacent to the boundary between the first non-folding region NFA1 and the folding region FA. More specifically, the first curved part B1 may have a specific curvature, and the virtual center of the specific curvature may be formed lower than the top surface US of the glass substrate GP.

A portion, which is adjacent to the boundary between the second non-folding region NFA2 and the folding region FA, of the first sloped part SP2 may have the shape curved in the thickness direction of the glass substrate GP, and the top surface US of the glass substrate GP may be formed as a curved surface. In other words, the top surface US of the glass substrate GP may include a curved part (hereinafter, referred as a “first curved part B2”) in the portion adjacent to the boundary between the second non-folding region NFA2 and the folding region FA. More specifically, the second curved part B2 may have a specific curvature, and the virtual center of the specific curvature may be formed lower than the top surface US of the glass substrate GP.

According to an embodiment of the present disclosure, a length (b) of the third flat part FLP3 of the recess part RP may range from 0 mm to 25 mm. However, the length (b) of the third flat part FLP3 of the recess part RP is not limited thereto.

According to an embodiment of the present disclosure, an angle (d°) of the slop formed in the glass substrate GP may be less than 0.4°. More specifically, the angle formed between the top surface US of the glass substrate GP in the first slot part SP1 and the top surface US of the glass substrate GP in the third flat part FLP3 may be 179.6° or more, and the angle formed between the top surface US of the glass substrate GP in the second slot part SP2 and the top surface US of the glass substrate GP in the third flat part FLP3 may be at less 179.6°. However, the angle of the slop formed in the glass substrate GP is not limited thereto.

According to an embodiment of the present disclosure, the gradient of the slop formed in the glass substrate GP may be less than 0.007°. In this case, the gradient of the slope formed in the glass substrate GP may refer to a value obtained by dividing a depth (c) of the slope by a width (a) of the slope. The depth (c) of the slope may be a vertical distance (c) between the first flat part FLP1 and the third flat part FLP3. However, the gradient of the slop formed in the glass substrate GP is not limited thereto.

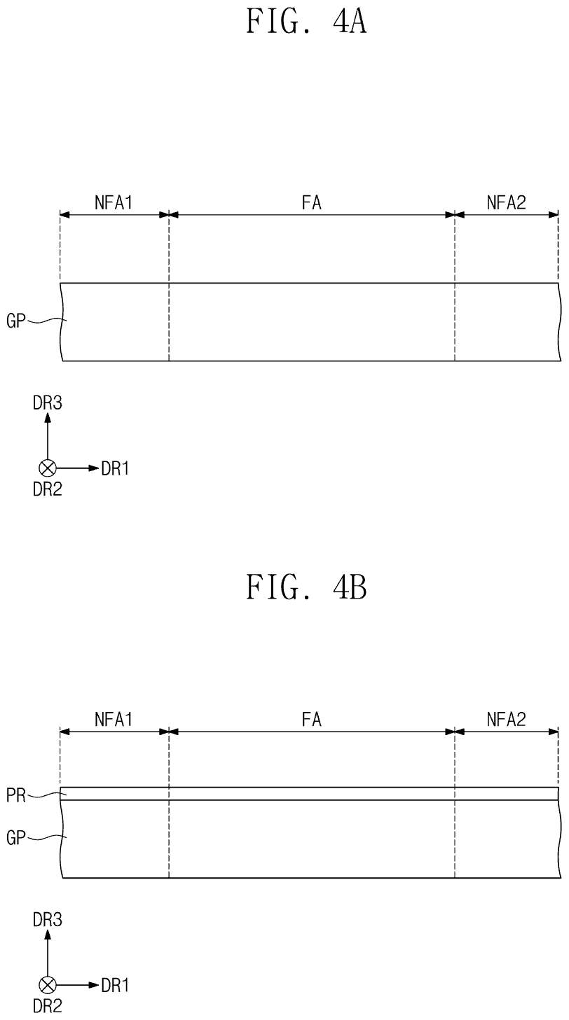

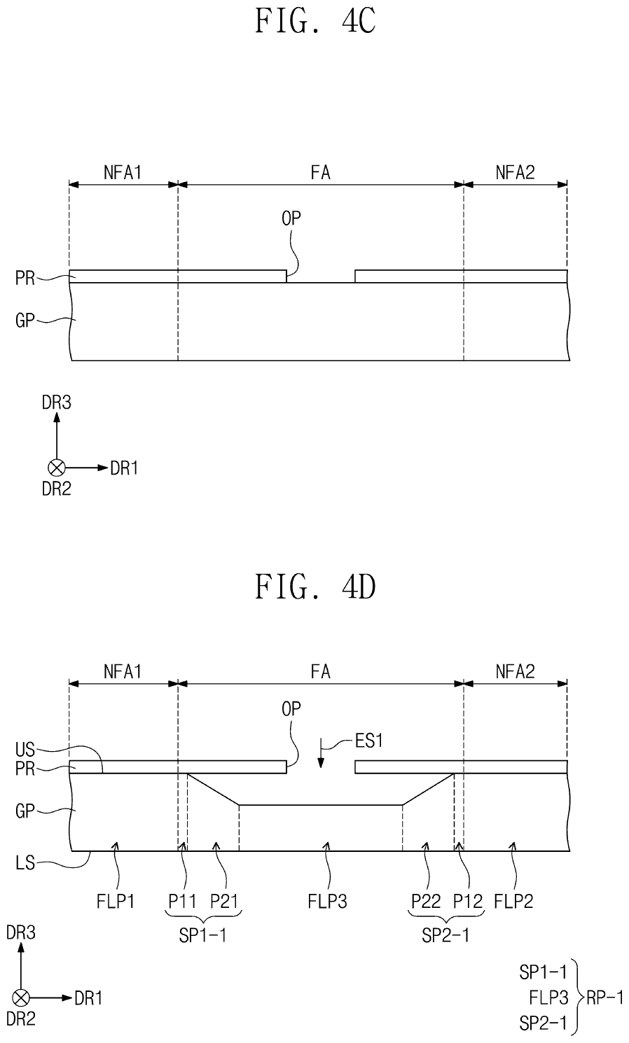

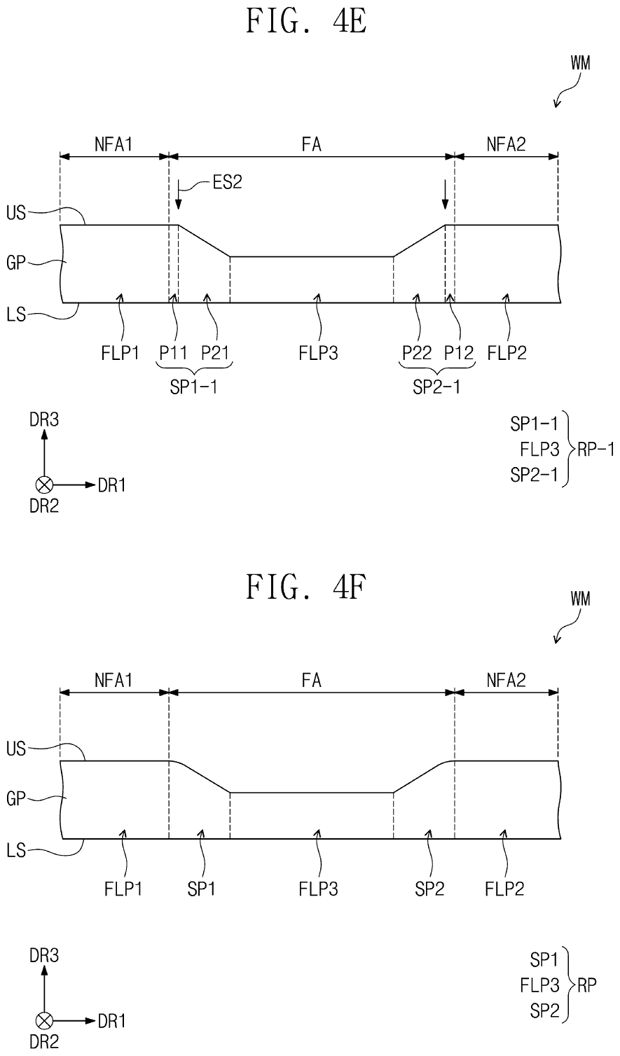

FIGS. 4A to 4E are cross-sectional views schematically illustrating steps in a method for manufacturing the window WM (see FIG. 3) according to an embodiment of the present disclosure.

Referring to FIGS. 4A to 4E, the method for manufacturing the window WM (see FIG. 3) according to an embodiment may include providing the glass substrate GP, forming a photoresist layer PR on the glass substrate GP, forming an opening pattern OP in the photoresist layer PR, etching the glass substrate GP by supplying first etchant ES1, removing the photoresist layer PR, and polishing at least a portion of the glass substrate GP. In the following description made with reference to FIGS. 4A to 4E, the same/similar reference numerals will be assigned to the same/similar components to components described with reference to FIG. 3 and the redundant duplication will be omitted.

Referring to FIG. 4A, the method for manufacturing the window WM (see FIG. 3) according to an embodiment of the present disclosure includes providing the glass substrate GP. In the providing of the glass substrate GP, the glass substrate GP may include the first non-folding region NFA1, the second non-folding region NFA2, and the folding region FA between the first and second non-folding regions NFA1 and NFA2. The first non-folding region NFA1, the second non-folding region NFA2, and the folding region FA defined in the glass substrate GP may correspond to the first non-folding region NFA1 (see FIG. 1A), the second non-folding region NFA2 (see FIG. 1A), and the folding region FA (see FIG. 1A) defined in the display device DD (see FIG. 1A).

Referring to FIG. 4A, the method for manufacturing the window WM (see FIG. 3) according to an embodiment of the present disclosure includes forming the photoresist layer PR on the glass substrate GP. The photoresist layer PR may be provided such that the photoresist layer PR overlaps with an entirety of the top surface US of the glass substrate GP. The photoresist layer PR may be provided such that the photoresist layer PR overlaps with the first non-folding region NFA1, the second non-folding region NFA2, and the folding region FA between the first and second non-folding regions NFA1 and NFA2.

Referring to FIG. 4C, the method for manufacturing the window WM (see FIG. 3) according to an embodiment of the present disclosure includes forming the opening OP in the photoresist layer PR. In the forming of the opening OP in the photoresist layer PR, the opening pattern OP may be formed such that the opening pattern OP overlaps with at least a portion of the folding region FA. The opening pattern OP may be formed to be in a non-overlap state with the first non-folding region NFA1 and the second non-folding region NFA2.

Referring to FIGS. 4C and 4D, the method for manufacturing the window WM (see FIG. 3) according to an embodiment of the present disclosure includes forming the opening OP in the photoresist layer PR and etching the glass substrate GP. In the etching of the glass substrate GP using the first etchant ES1, the first etchant ES1 may be supplied to the top surface US of the glass substrate GP exposed through the opening pattern OP formed in the photoresist layer PR. According to an embodiment, the first etchant ES1 may include hydrofluoric acid (NH₄HF₂). Accordingly, the glass substrate GP may have a recessed shape in at least a portion of the folding region FA. A recess may be formed in the folding region FA of the glass substrate GP. The recess may have a depth lower than the depth of the glass substrate GP before the etching process is performed.

The first flat part FLP1, the second flat part FLP2, and an initial recess part RP-1 between the first flat part FLP1 and the second flat part FLP2 may be formed in the etched glass substrate GP.

The first flat part FLP1 may correspond to the first non-folding region NFA1, the second flat part FLP2 may correspond to the second non-folding region NFA2, and the initial recess part RP-1 may correspond to the folding region FA. The initial recess part RP-1 may be recessed from the first and second flat parts FLP1 and FLP2 in the thickness direction of the glass substrate GP. In other words, the thickness of the glass substrate GP in the initial recess part RP-1 may be smaller than the thickness of the glass substrate GP in the first and second flat parts FLP1 and FLP2.

The initial recess part RP-1 may include a first step part SP1-1 adjacent to the first non-folding region NFA1, a second step part SP2-1 adjacent to the second non-folding region NFA2, and a third flat part FLP3 between the first and second step parts SP1-1 and SP2-1.

The third flat part FLP3 may be defined as a part parallel to the bottom surface LS of the glass substrate GP. The third flat part FLP3 may overlap with the opening pattern OP. The thickness of the glass substrate GP in the third flat part FLP3 may be smaller than the thickness of the glass substrate GP in the first and second flat parts FLP1 and FLP2. The width of the third flat part FLP3 may be wider than the width of the opening pattern OP.

The first step part SP1-1 may include a (1-1)-th part P11, which is adjacent to the first non-folding region NFA1 and flat, and a (2-1)-th part P21 which is adjacent to the third flat part FLP3 and sloped. The top surface US in the (1-1)-th part P11 of the first step part SP1-1 may extend from the top surface US in the first non-folding region NFA1 while being flat.

The second step part SP2-1 may include a (1-2)-th part P12, which is adjacent to the second non-folding region NFA2 and flat, and a (2-2)-th part P22 which is adjacent to the third flat part FLP3 and sloped. The top surface US in the (1-2)-th part P12 of the second step part SP2-1 may extend from the top surface US in the second non-folding region NFA2 while being flat.

Referring to FIGS. 4D and 4E, the method for manufacturing the window WM (see FIG. 3) according to an embodiment of the present disclosure includes removing the photoresist layer PR and polishing the at least a portion of the glass substrate GP. In this specification, the meaning of “polishing” is a wider meaning of performing a process for making the top surface US of the glass substrate GP a relatively smoother surface. More specifically, the meaning of “polishing” may include making a starting part of the recess and a part adjacent to the starting part curved in the thickness direction of the glass substrate GP. The meaning of “polishing” may include making the top surface US of the glass substrate GP a relatively smoother surface through a chemical reaction and/or a physical contact.

In the polishing of the at least a portion of the glass substrate GP, after removing the photoresist layer PR from the top surface US of the glass substrate GP, the method may include supplying the second etchant ES2 to the top surface US of the glass substrate GP. According to an embodiment, the second etchant ES2 may be the same as the first etchant ES1 supplied in the etching of the glass substrate GP. According to an embodiment, the second etchant ES2 may be hydrofluoric acid (NH₄HF₂).

According to an embodiment of the present disclosure, the method may include supplying the second etchant ES2 only to a partial region of the top surface US of the glass substrate GP. For example, the method may include supplying the second etchant ES2 only to a portion, which is adjacent to the boundary between the first non-folding region NFA1 and the folding region FA, of the first step part SP1-1, and to a portion, which is adjacent to the boundary between the second non-folding region NFA2 and the folding region FA, of the second step part SP2-1. Though FIG. 4E illustrates that the second etchant ES2 is supplied only to a portion of the top surface US of the glass substrate GP, embodiments supported the present disclosure are not limited thereto. For example, the second etchant ES2 may be supplied to the entire surface of the top surface US of the glass substrate GP.

In the polishing of the at least a portion of the glass substrate GP, the recess part RP may be formed from the initial recess part RP-1. The recess part RP may include the first sloped part SP1 adjacent to the first non-folding region NFA1, the second sloped part SP2 adjacent to the second non-folding region NFA2, and the third flat part FLP3 interposed between the first and second sloped parts SP1 and SP2.

The method may include supplying the second etchant ES2 to a region adjacent to a starting part of a recess in the first part SP1-1. The portion, which is adjacent to the boundary between the first non-folding region NFA1 and the folding region FA, of the first step part SP1-1 is polished to form the first sloped part SP1 curved in the portion, which is adjacent to the boundary between the first non-folding region NFA1 and the folding region FA, of the first step part SP1-1. The portion, which is adjacent to the boundary between the first non-folding region NFA1 and the folding region FA, of the first sloped part SP1 may have the shape curved in the thickness direction of the glass substrate GP, and the top surface US of the glass substrate GP in the portion may be formed as a curved surface.

The method may include supplying the second etchant ES2 to a region adjacent to a starting part of a recess in the second step part SP2-1. The portion, which is adjacent to the boundary between the second non-folding region NFA2 and the folding region FA, of the second step part SP2 is polished to form the second sloped part SP2 curved in the portion, which is adjacent to the boundary between the second non-folding region NFA2 and the folding region FA, of the second step part SP2-1. The portion, which is adjacent to the boundary between the second non-folding region NFA2 and the folding region FA, of the second sloped part SP2 may have the shape curved in the thickness direction of the glass substrate GP, and the top surface US of the glass substrate GP in the portion may be formed as a curved surface.

In the polishing of the at least a portion of the glass substrate GP, the second etchant ES2, which is supplied to the region adjacent to the starting part of the recess in the first step part SP1-1, may flow along the top surface US of the glass substrate GP toward the third flat part FLP3 from the flat region in the first step part SP1-1. Accordingly, the region adjacent to the starting part of the recess in the first step part SP1-1 may be formed to be more curved. That is, for example, the region may have an increased curvature compared to a curvature of the region prior to supplying the second etchant ES2 to the region. The folding region FA of the glass substrate GP may be more gently sloped.

The second etchant ES2, which is supplied to the region adjacent to the starting part of the recess in the second step part SP2-1, may flow along the top surface US of the glass substrate GP toward the folding region FA from the second non-folding region NFA2. Accordingly, the region adjacent to the starting part of the recess in the second step part SP2-1 may be formed to be more curved. Accordingly, for example, the folding region FA of the glass substrate GP may be more gently sloped. Accordingly, the failure of the etched step caused due to the clear boundary line between an etched portion and a non-etched portion may be overcome.

Unlike the present disclosure, when the glass substrate GP is polished using a polishing agent, such as, for example, alumina or silica, particles present in the polishing agent may damage the glass substrate GP. In some aspects, the polishing using the polishing agent results in a lower polishing speed and an increased amount of time for the polishing, as compared to the polishing using an etchant. According to the polishing of the glass substrate GP to manufacture the window WM of the present disclosure, the glass substrate GP is not damaged and the time involved for polishing may be shortened, as compared when the glass substrate GP is polished using the polishing agent such as, for example, alumina or silica.

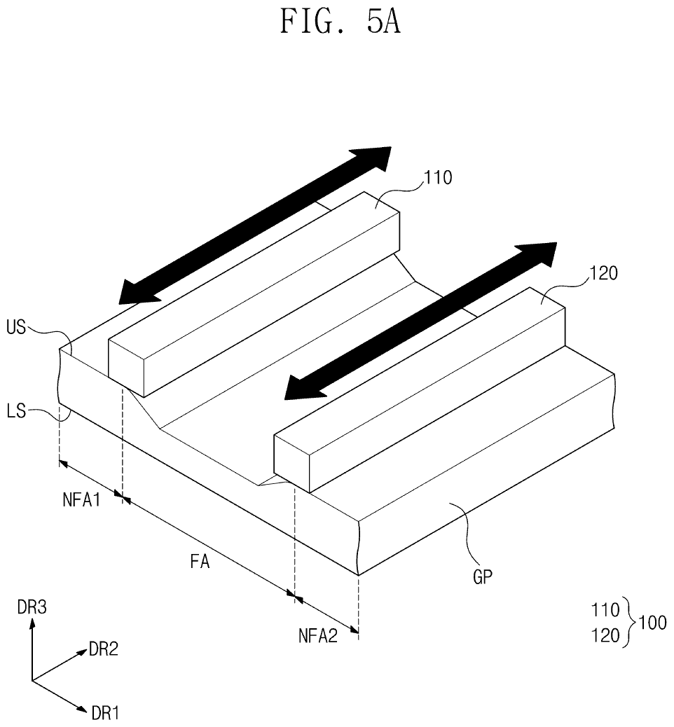

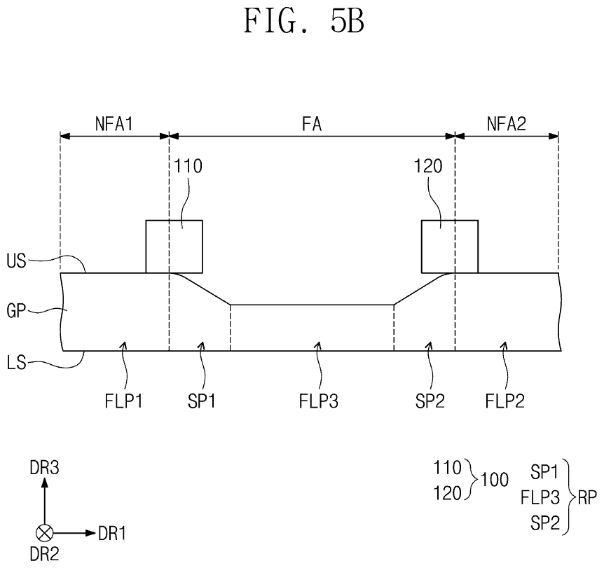

FIGS. 5A and 5B are a perspective view and a cross-sectional view schematically illustrating a polishing step in a method for manufacturing a window according to an embodiment of the present disclosure.

In the following description made with reference to FIGS. 5A to 5E, the same/similar reference numerals will be assigned to the same/similar components to components described with reference to FIGS. 3 to 4E and the redundant duplication will be omitted.

Referring to FIGS. 5A and 5B, in the polishing of the at least a portion of the glass substrate GP according to an embodiment, a polishing tool 100 may be further provided. The method may be performed using the polishing tool 100. The polishing tool 100 may include a first polishing tool 110 and a second polishing tool 120.

The first polishing tool 110 may be provided such that a portion of the first polishing tool 110 is overlapped with the (1-1)-th part P11, which is adjacent to the first non-folding region NFA1, of the first step part SP1-1. The first polishing tool 110 may be provided such that the first polishing tool 110 makes contact with the top surface US in the (1-1)-th part P11. In the present specification, the meaning of “the polishing tool 100 is overlapped with a certain region” may include the meaning of “at least a portion of the polishing tool 100 is overlapped with at least a portion of the region”.

The second polishing tool 120 may be provided such that a portion of the second polishing tool 120 is overlapped with the (1-2)-th part P12, which is adjacent to the second non-folding region NFA2, of the second step part SP2-1. The second polishing tool 120 may be provided such that the second polishing tool 120 makes contact with the top surface US in the (1-2)-th part P12.

The first polishing tool 110 may polish a region, which is adjacent to a starting part of the recess in the first step part SP1-1, of the top surface US of the glass substrate GP. The portion, which is adjacent to the boundary between the first non-folding region NFA1 and the folding region FA, of the first step part SP1-1 is polished to form the first sloped part SP1 curved in the portion, which is adjacent to the boundary between the first non-folding region NFA1 and the folding region FA, of the first step part SP1-1. A portion, which is adjacent to the boundary between the first non-folding region NFA1 and the folding region FA, of the first sloped part SP1 may have the shape curved in the thickness direction of the glass substrate GP, and the top surface US of the glass substrate GP in the portion may be formed as a curved surface.

The second polishing tool 120 may polish a region, which is adjacent to a starting part of the recess in the second step part SP2-1, of the top surface US of the glass substrate GP. The portion, which is adjacent to the boundary between the second non-folding region NFA2 and the folding region FA, of the second step part SP2-1 is polished to form the second sloped part SP2 curved in the portion, which is adjacent to the boundary between the second non-folding region NFA2 and the folding region FA, of the second step part SP2-1. The portion, which is adjacent to the boundary between the second non-folding region NFA2 and the folding region FA, of the second sloped part SP2 may have the shape curved in the thickness direction of the glass substrate GP, and the top surface US of the glass substrate GP in the portion may be formed as a curved surface.

According to an embodiment, each of the first and second polishing tools 110 and 120 reciprocates in one direction to perform the polishing step. Although FIG. 5A illustrates that each of the first and second polishing tools 110 and 120 reciprocates in the second direction DR2 and the direction opposite to the second direction DR2, an embodiment is not limited thereto. For example, the moving directions of the first and second polishing tools 110 and 120 may be set variously. According to an embodiment, the first polishing tool 110 and the second polishing tool 120 may not be provided in the form of rotating tools. However, according to an embodiment, the first polishing tool 110 and the second polishing tool 120 may be provided in the form of the rotating tools to rotate while reciprocating in the second direction DR2 and the direction opposite to the second direction DR2.

In the polishing of the at least a portion of the glass substrate GP, the method may include supplying the second etchant ES2 to the top surface of the glass substrate GP while the polishing for the top surface US of the glass substrate GP is performed by the first polishing tool 110 and the second polishing tool 120 and/or before the polishing is performed. According to an embodiment, the second etchant ES2 may be supplied through a supply pipe (not illustrated). According to an embodiment, the second etchant ES2 may be supplied through a fluid passage provided in the polishing tool 100. According to an embodiment, the second etchant ES2 may be supplied through a nozzle (not illustrated).

According to an embodiment, the polishing tool 100 may include a porous material to absorb the second etchant ES2 supplied to the top surface US of the glass substrate GP. The polishing tool 100 may include a material, such as, for example, sponge, polyurethane, hog bristle, polycarbonate (PC), nylon, carpet, mixed wool, or foam. As the second etchant ES2 is absorbed by the polishing tool 100, the second etchant ES2 is prevented from being supplied to other regions of the top surface US of the glass substrate GP (e.g., regions of the top surface US for which polishing is not to be performed), thereby preventing polishing from being unnecessarily performed.

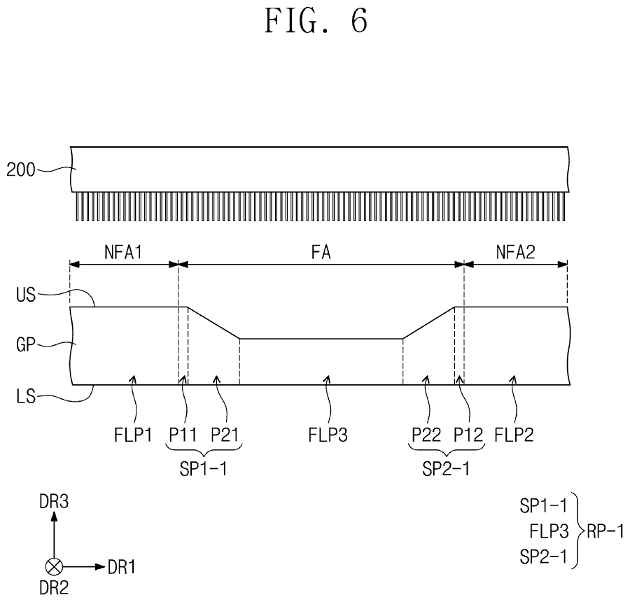

FIG. 6 is a perspective view schematically illustrating a polishing step in a method for manufacturing the window WM according to an embodiment of the present disclosure. In the following description made with reference to FIG. 6, the same/similar reference numerals will be assigned to the same/similar components to components described with reference to FIGS. 3 to 5B and the redundant duplication will be omitted.

Referring to FIG. 6, according to an embodiment of the present disclosure, a polishing tool 200 may be provided such that the polishing tool 200 overlaps with the entire surface of the top surface US of the glass substrate GP. The polishing tool 200 may overlap with the first non-folding region NFA1, the second non-folding region NFA2, and the folding region FA.

The method may include supplying the second etchant ES2 (see FIG. 4E) to the top surface US of the glass substrate, while and/or before the polishing for the top surface US of the glass substrate GP is performed by the second polishing tool 200. According to an embodiment, the second etchant ES2 (see FIG. 4A) may be supplied through a supply plate (not illustrated) According to an embodiment, the second etchant ES2 (see FIG. 4E) may be supplied through a fluid passage provided in the polishing tool 200. According to an embodiment, the second etchant ES2 (see FIG. 4E) may be supplied through a nozzle (not illustrated).

According to an embodiment, the polishing tool 200 may be provided in the form of a brush. However, the form of the polishing tool 200 is not limited thereto. For example, the polishing tool 200 may include a porous material to absorb the second etchant ES2 (see FIG. 4E) supplied to the top surface US of the glass substrate GP. For example, the polishing tool 200 may include a material such as, for example, sponge, polyurethane, hog bristle, polycarbonate (PC), nylon, carpet, mixed wool, or foam. In other words, the polishing tool 200 including the porous material may be provided such that the polishing tool 200 overlaps with the entire surface of the top surface US of the glass substrate GP.

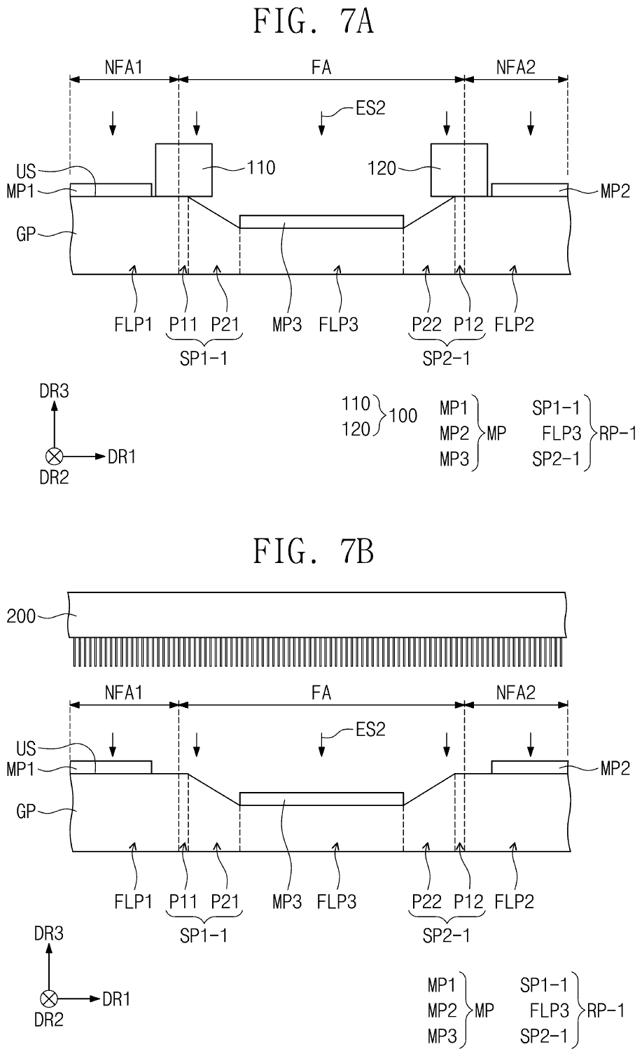

FIGS. 7A and 7B are cross-sectional views schematically illustrating a polishing step in the method for manufacturing the window WM according to an embodiment of the present disclosure. In the following description made with reference to FIG. 7, the same/similar reference numerals will be assigned to the same/similar components to components described with reference to FIGS. 3 to 5B and the redundant duplication will be omitted.

Referring to FIGS. 7A and 7B, according to an embodiment of the present disclosure, the method may further include forming a masking pattern MP which covers a portion of the top surface US of the glass substrate GP, after removing the photoresist layer PR having the opening pattern OP and before polishing the at least a portion of the glass substrate GP.

The glass substrate GP illustrated in FIGS. 7A and 7B may have the first flat part FLP1, the second flat part FLP2, and the initial recess part RP-1 interposed between the first flat part FLP1 and the second flat part FLP2 which are formed by polishing the glass substrate GP. The initial recess part RP-1 may include the first step part SP1-1 adjacent to the first non-folding region NFA1, the second step part SP2-1 adjacent to the second non-folding region NFA2, and the third flat part FLP3 between the first and second step parts SP1-1 and SP2-1. The masking pattern MP may not be formed on a portion, which is to be polished, of the top surface US of the glass substrate GP.

The masking pattern MP may include a first masking pattern MP1, a second masking pattern MP2, and a third masking pattern MP3. The first masking pattern MP1 may be disposed on the first flat part FLP1, the second masking pattern MP2 may be disposed on the second flat part FLP2, and the third masking pattern MP3 may be disposed on the third flat part FLP3.

The first masking pattern MP1 may directly make contact with at least a portion of the top surface US in the first non-folding region NFA1 and cover the at least a portion of the top surface US in the first non-folding region NFA1. The second masking pattern MP2 may directly make contact with at least a portion of the top surface US in the second non-folding region NFA2 and cover the at least a portion of the top surface US in the second non-folding region NFA2. The third masking pattern MP3 may directly make contact with at least a portion of the top surface US in the third flat part FLP3 and cover the at least a portion of the top surface US in the third flat part FLP3.

According to an embodiment, the masking pattern MP may be provided in the form of a tape or a film.

After forming the masking pattern MP which covers a portion of the top surface US of the glass substrate GP, the method may include supplying second etchant ES2 to the top surface US of the glass substrate GP in the polishing of the at least a portion of the glass substrate GP. According to an embodiment, the second etchant ES2 may be the same as the first etchant ES1 supplied in the etching of the glass substrate GP. According to an embodiment, the second etchant ES2 may be hydrofluoric acid (NH₄HF₂).

For example, the second etchant ES2 may be supplied to the entire surface of the top surface US of the glass substrate GP. Even if the second etchant ES2 is supplied to the portion of the top surface US of the glass substrate GP which is not to be polished, the masking pattern MP formed may prevent the portion from being polished. Embodiments of the present disclosure, however, are not limited thereto. For example, in some example implementations, the second etchant ES2 may be supplied to a portion of the top surface US of the glass substrate GP, without supplying the second etchant ES2 to the entirety of the top surface US.

Referring to FIGS. 7A and 7B, the polishing tools 110 and 120 may be further provided in the polishing of the at least a portion of the glass substrate GP. According to an embodiment, portions of the polishing tools 110 and 120 may be provided such that the portions overlap with the first masking pattern MP1, the second masking pattern MP2, and the third masking pattern MP3. Even if the polishing tools 110 and 120 make contact with the region, which is not to be polished, of the top surface US of the glass substrate GP, the first masking pattern MP1, the second masking pattern MP2, and the third masking pattern MP3 may prevent or protect the region from being polished.

Referring to FIG. 7A, according to an embodiment, the polishing tool 100 may include the first polishing tool 110 and the second polishing tool 120. The first polishing tool 110 may be provided between the first masking pattern MP1 and the third masking pattern MP3 and the second polishing tool 120 may be provided between the second masking pattern MP2 and the third masking pattern MP3. In the process of directly making, by the first and second polishing tools 110 and 120, contact with the top surface US of the glass substrate GP while polishing (e.g., the process of reciprocating or rotating by the first and second polishing tools 110 and 120), even if the polishing tool 100 makes contact with the region, which is not to be polished, of the top surface US of the glass substrate GP, the first masking pattern MP1, the second masking pattern MP2, and the third masking pattern MP3 may prevent or protect the region from being polished.

Referring to FIG. 7, according to an embodiment, the polishing tool 200 may be provided such that the polishing tool 200 overlaps with the entire surface of the top surface US of the glass substrate GP. The polishing tool 200 may overlap with all the first non-folding region NFA1, the second non-folding region NFA2, and the folding region FA. Even if the polishing tool 200 makes contact with the region, which is not to be polished, of the top surface US of the glass substrate GP, the first masking pattern MP1, the second masking pattern MP2, and the third masking pattern MP3 may prevent or protect the region from being polished.

Referring to FIGS. 7A and 7B, the method may include supplying the second etchant ES2 to the top surface of the glass substrate GP while the polishing of the top surface US of the glass substrate GP is performed by the first polishing tool 110 and the second polishing tool 120 and/or before the polishing is performed. Although FIGS. 7A and 7B illustrate that all the second etchant ES2 and the polishing tools 110 and 120 are provided, an embodiment is not limited thereto. According to an embodiment, the polishing tools 110 and 120 may be provided after the second etchant ES2 is supplied to the top surface US of the glass substrate GP. According to an embodiment, the second etchant ES2 may be supplied after the polishing tools 110 and 120 are provided on the top surface US of the glass substrate GP.

According to an embodiment, the second etchant ES2 may be supplied through a supply pipe (not illustrated). According to an embodiment, the second etchant ES2 may be supplied through a fluid passage provided in the polishing tools 110 and 120. According to an embodiment, the second etchant ES2 may be supplied through a nozzle (not illustrated).

According to an embodiment, the polishing tools 110 and 120 may include a porous material to absorb the second etchant ES2 supplied to the top surface US of the glass substrate GP. The polishing tools 110 and 120 may include a material such as, for example, sponge, polyurethane, hog bristle, polycarbonate (PC), nylon, carpet, mixed wool, or foam.

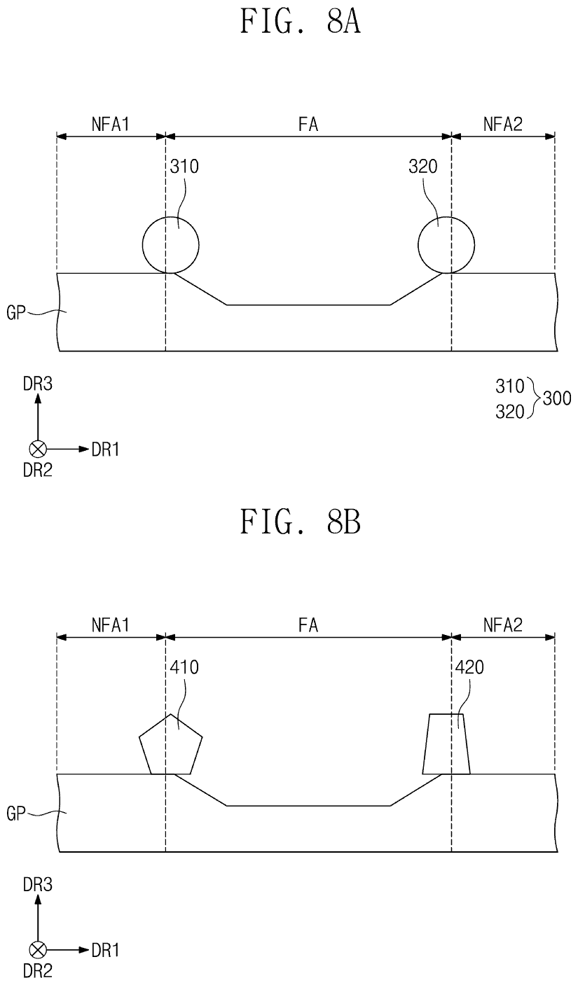

FIGS. 8A and 8B are cross-sectional views schematically illustrating a polishing step in a method for manufacturing the window WM according to an embodiment of the present disclosure.

Referring to FIG. 8A, a polishing tool 300 may be further provided in the polishing of the at least a portion of the glass substrate GP. The polishing tool 300 may include a first polishing tool 310 and a second polishing tool 320. According to an embodiment, the first polishing tool 310 and the second polishing tool 320 may be provided in a cylinder shape. According to an embodiment, the first polishing tool 310 and the second polishing tool 320 may respectively be provided as the same prism shape.

Referring to FIG. 8B, according to an embodiment, a first polishing tool 410 and a second polishing tool 420 may be provided in a polygonal prism shape. According to an embodiment, the first polishing tool 410 and the second polishing tool 420 may be provided in in different prims shapes. Although FIG. 8B illustrates that the first polishing tool 410 and the second polishing tool 420 may have mutually different shapes, an embodiment is not limited thereto. According to an embodiment, the first polishing tool 410 and the second polishing tool 420 may be provided in the same prism shape.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

According to the present disclosure, the etchant is additionally supplied after performing etching a glass substrate etching step to polish the boundary part between the folding region and the non-folding region, such that the boundary part between the folding region and the non-folding region is curved, thereby reducing or preventing the failure of the etched step. Accordingly, the window improved in the strength of impact resistance and the defective outer appearance may be provided.

Although an embodiment of the present disclosure has been described for illustrative purposes, those skilled in the art will appreciate that various modifications, and substitutions are possible, without departing from the scope and spirit of the present disclosure as disclosed in the accompanying claims. Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method for manufacturing a window, the method comprising:
providing a glass substrate comprising a first non-folding region, a second non-folding region, and a folding region interposed between the first non-folding region and the second non-folding region;
forming a photoresist layer on the glass substrate;
forming an opening pattern in the photoresist layer, wherein the opening pattern overlaps with the folding region and exposes the glass substrate;
etching the glass substrate by supplying a first etchant to the glass substrate exposed through the opening pattern;
removing the photoresist layer having the opening pattern; and
polishing at least a portion of the glass substrate by supplying a second etchant to a top surface of the glass substrate.

2. The method of claim 1, wherein the first etchant is the same as the second etchant.

3. The method of claim 1, wherein in the polishing of the at least the portion of the glass substrate, the second etchant is supplied to an entirety of the top surface of the glass substrate.

4. The method of claim 1, wherein, in the etching of the glass substrate a recess is formed in at least a portion of the folding region.

5. The method of claim 1, wherein in the etching of the glass substrate, a first flat part, a second flat part, and an initial recess part interposed between the first flat part and the second flat part are formed in the glass substrate.

6. The method of claim 5, wherein the initial recess part comprises:
a first step part adjacent to the first non-folding region,
a second step part adjacent to the second non-folding region, and
a third flat part interposed between the first step part and the second step part.

7. The method of claim 6, wherein in the polishing of the at least the portion of the glass substrate:
a recess part is formed from the initial recess part,
a portion of the first step part is polished, and the polishing of the portion of the first step part forms a first sloped part curved in the portion of the first step part, wherein the portion of the first step part which is polished and in which the first sloped part is formed is adjacent to a boundary between the first non-folding region and the folding region, and
a portion of the second step part is polished, and the polishing of the portion of the second step part forms a second sloped part curved in the portion of the second step part, wherein the portion of the second step part which is polished and in which the second sloped part is formed is adjacent to a boundary between the second non-folding region and the folding region,
wherein the recess part comprises the first sloped part, the second sloped part, and the third flat part.

8. The method of claim 7, wherein in the polishing of the at least the portion of the glass substrate, the second etchant is supplied to:
the portion, which is adjacent to the boundary between the first non-folding region and the folding region, of the first step part, and
the portion, which is adjacent to the boundary between the second non-folding region and the folding region, of the second step part.

9. The method of claim 8, wherein the polishing of the at least the portion of the glass substrate is performed using a polishing tool, wherein the polishing tool is provided such that the polishing tool overlaps with an entirety of the top surface of the glass substrate,
wherein the polishing tool comprises a porous material.

10. The method of claim 9, wherein:
the polishing tool comprises a first polishing tool and a second polishing tool,
the first polishing tool is provided such that the first polishing tool overlaps with the portion, which is adjacent to the boundary between the first non-folding region and the folding region, of the first step part, and
the second polishing tool is provided such that the first polishing tool overlaps with the portion, which is adjacent to the boundary between the second non-folding region and the folding region, of the second step part.

11. The method of claim 10, wherein:
the first polishing tool is provided to have a portion overlapped with a flat portion, which is adjacent to the first non-folding region, of the first step part, and to make contact with a top surface of the flat portion, and
the second polishing tool is provided to have a portion overlapped with a flat portion, which is adjacent to the second non-folding region, of the second step part, and to make contact with a top surface of the flat portion.

12. The method of claim 1, further comprising:
forming a masking pattern configured to cover a portion of the top surface of the glass substrate, after the removing the photoresist layer having the opening pattern and before the polishing at least a portion of the glass substrate.

13. A method for manufacturing a window, the method comprising:
providing a glass substrate comprising a first non-folding region, a second non-folding region, and a folding region interposed between the first non-folding region and the second non-folding region;
forming a photoresist layer on the glass substrate;
forming an opening pattern in the photoresist layer, wherein the opening pattern overlaps with the folding region and exposes the glass substrate;
etching the glass substrate by supplying a first etchant to the glass substrate exposed through the opening pattern;
removing the photoresist layer having the opening pattern;
forming a masking pattern configured to cover a portion of a top surface of the glass substrate; and
polishing at least a portion of the glass substrate,
wherein in the etching of the glass substrate, a first flat part, a second flat part, and an initial recess part interposed between the first flat part and the second flat part are formed on the glass substrate.

14. The method of claim 13, wherein the masking pattern is not formed on a portion, which is to be polished, of the top surface of the glass substrate.

15. The method of claim 13, wherein:
in the polishing of the at least a portion of the glass substrate, a second etchant is supplied to the top surface of the glass substrate, and
the first etchant is the same as the second etchant.

16. The method of claim 13, wherein the initial recess part comprises:
a first step part adjacent to the first non-folding region,
a second step part adjacent to the second non-folding region, and
a third flat part interposed between the first step part and the second step part, and
the masking pattern comprises:
a first masking pattern, a second masking pattern, and a third masking pattern, and
the first masking pattern is disposed on the first flat part, the second masking pattern is disposed on the second flat part, and the third masking pattern is disposed on the third flat part.

17. The method of claim 16, wherein:
the first step part comprises:
a part adjacent to the first non-folding region and flat, and
a part adjacent to the third flat part and sloped, and
the second step part comprises:
a part adjacent to the second non-folding region and flat, and
a part adjacent to the third flat part and sloped.

18. The method of claim 16, wherein in the polishing of the at least the portion of the glass substrate:
a recess part is formed from the initial recess part,
a portion of the first step part is polished, and the polishing of the portion of the first step part forms a first sloped part curved in the portion of the first step part, wherein the portion of the first step part which is polished and in which the first sloped part is formed is adjacent to a boundary between the first non-folding region and the folding region, and,
a portion of the second step part is polished, and the polishing of the portion of the second step part forms a second sloped part curved in the portion of the second step part, wherein the portion of the second step part which is polished and in which the second sloped part is formed is adjacent to a boundary between the second non-folding region and the folding region,
wherein the recess part comprises the first sloped part, the second sloped part, and the third flat part.

19. The method of claim 13, wherein the polishing of the at least a portion of the glass substrate is performed using a polishing tool,
wherein the polishing tool is provided such that a portion of the polishing tool overlaps with the masking pattern.

20. The method of claim 19, wherein:
the polishing tool comprises:
a first polishing tool and a second polishing tool, and
the masking pattern comprises:
a first masking pattern, a second masking pattern, and a third masking pattern,
the first polishing tool is provided between the first masking pattern and the second masking pattern, and
the second polishing tool is provided between the second masking pattern and the third masking pattern.
